(19) United States
(12) Patent Application Publication
(10) Pub. No.: US 2025/0126829 A1
(43) Pub. Date: Apr. 17, 2025

(54) GATE CUT STRUCTURE INCLUDING AN AIRGAP

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Oleg Gluschenkov, Tannersville, NY (US)

(21) Appl. No.: 18/486,724

(22) Filed: Oct. 13, 2023

(51) Int. Cl. H01L 29/78; H01L 29/06; H01L 29/423; H01L 29/66; H01L 29/775; H01L 29/786

(52) U.S. Cl. CPC H10D 30/611; H10D 30/014; H10D 30/43; H10D 30/6735; H10D 30/6757; H10D 62/116; H10D 62/121; H10D 64/017

(57) ABSTRACT

A semiconductor device comprises a gate cut portion disposed between a first gate region and a second gate region. The gate cut portion comprises a dielectric liner layer disposed around a vacant area. The dielectric liner layer encloses the vacant area, and the gate cut portion isolates the first gate region from the second gate region.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments of the invention provide techniques for forming a gate cut structure including an airgap.

In one embodiment, a semiconductor device comprises a gate cut portion disposed between a first gate region and a second gate region. The gate cut portion comprises a dielectric liner layer disposed around a vacant area. The dielectric liner layer encloses the vacant area, and the gate cut portion isolates the first gate region from the second gate region.

As may be combined with the preceding paragraph, the vacant area may comprise air. The first gate region and the second gate region may contact the dielectric liner layer of the gate cut portion. The gate cut portion can be further disposed between a first source/drain region and a second source/drain region. A source/drain contact may be disposed on one of the first source/drain region and the second source/drain region, wherein part of the gate cut portion contacts the source/drain contact. The source/drain contact may be disposed on a first side of the one of the first source/drain region and the second source/drain region. The semiconductor device may further comprise a semiconductor placeholder layer disposed on a second side of the one of the first source/drain region and the second source/drain region opposite the first side. One of the first source/drain region and the second source/drain region is connected to a backside power delivery network through a backside source/drain contact.

As may be combined with the preceding paragraphs, part of the gate cut portion may be disposed in an isolation region, and a spacer layer may be disposed between the isolation region and the part of the gate cut portion. The part of the gate cut portion disposed in the isolation region may comprise a pinched-off portion of the dielectric liner layer. A cap layer may be disposed on the first gate region, the second gate region and the gate cut portion, wherein the cap layer contacts the gate cut portion.

Advantageously, a gate cut portion that includes a vacant area comprising air (e.g., airgap) is formed from backside of a semiconductor device. The presence of the airgap advantageously reduces capacitance between gates of transistors. The airgap is formed after pinch-off of a dielectric liner layer deposited in a conformal deposition process (e.g., ALD or CVD). As an additional advantage, the gate cut portion is also disposed between source/drain regions. A cap layer disposed on the gate regions advantageously limits the depth of a backside gate cut so that frontside source/drain contacts in the path of the backside gate cut remain intact.

In another embodiment, a semiconductor device comprises a first nanosheet structure comprising a first gate region including a first plurality of gate structures, and a first plurality of channel layers alternately stacked with the first plurality of gate structures. The semiconductor device further comprises a second nanosheet structure comprising a second gate region including a second plurality of gate structures, and a second plurality of channel layers alternately stacked with the second plurality of gate structures. A gate cut portion is disposed between the first gate region and the second gate region, wherein the gate cut portion comprises a dielectric liner layer disposed around a vacant area. The dielectric liner layer encloses the vacant area, and the gate cut portion isolates the first gate region from the second gate region.

As may be combined with the preceding paragraphs, the vacant area may comprise air, and the first gate region and the second gate region may contact the dielectric liner layer of the gate cut portion.

As may be combined with the preceding paragraphs, a first source/drain region may be disposed on a side of the first nanosheet structure, and a second source/drain region may be disposed on a side of the second nanosheet structure. The gate cut portion may be further disposed between the first source/drain region and the second source/drain region.

As may be combined with the preceding paragraphs, a source/drain contact may be disposed on one of the first source/drain region and the second source/drain region, wherein part of the gate cut portion contacts the source/drain contact.

As may be combined with the preceding paragraphs, the semiconductor device may further comprise a cap layer disposed on the first gate region, the second gate region and the gate cut portion, wherein the cap layer contacts the gate cut portion.

In another embodiment, a semiconductor device comprises a first transistor comprising a first gate region, a second transistor comprising a second gate region, and an isolation structure disposed between and contacting the first gate region and the second gate region. The isolation structure comprises a dielectric liner layer disposed around a vacant area, wherein the dielectric liner layer encloses the vacant area.

As may be combined with the preceding paragraphs, wherein the vacant area may comprise air. The first transistor may further comprise a first source/drain region, and the second transistor may further comprise a second source/drain region. The gate cut portion may be further disposed between a first source/drain region and a second source/drain region.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure with lines X, Y1 and Y2 on which the cross-sectional views of FIGS. 2A-3C are based, according to an embodiment of the invention.

FIG. 2A depicts a first cross-sectional view corresponding to the line X in FIG. 1 following replacement metal gate (RMG) formation, according to an embodiment of the invention.

FIG. 2B depicts a second cross-sectional view corresponding to the line Y1 in FIG. 1 following RMG formation, according to an embodiment of the invention.

FIG. 2C depicts a third cross-sectional view corresponding to the line Y2 in FIG. 1 following RMG formation, according to an embodiment of the invention.

FIG. 3A depicts a first cross-sectional view corresponding to the line X in FIG. 1 following RMG recessing and frontside cap layer formation, according to an embodiment of the invention.

FIG. 3B depicts a second cross-sectional view corresponding to the line Y1 in FIG. 1 following RMG recessing and frontside cap layer formation, according to an embodiment of the invention.

FIG. 3C depicts a third cross-sectional view corresponding to the line Y2 in FIG. 1 following RMG recessing and frontside cap layer formation, according to an embodiment of the invention.

FIG. 4 depicts a top view of a semiconductor structure with lines X, Y1 and Y2 on which the cross-sectional views of FIGS. 5A-14C are based, according to an embodiment of the invention.

FIG. 5A depicts a first cross-sectional view corresponding to the line X in FIG. 4 following middle-of-line (MOL) metallization layer, via, gate contact and source/drain contact formation, according to an embodiment of the invention.

FIG. 5B depicts a second cross-sectional view corresponding to the line Y1 in FIG. 4 following MOL metallization layer, via, gate contact and source/drain contact formation, according to an embodiment of the invention.

FIG. 5C depicts a third cross-sectional view corresponding to the line Y2 in FIG. 4 following MOL metallization layer, via, gate contact and source/drain contact formation, according to an embodiment of the invention.

FIG. 6A depicts a first cross-sectional view corresponding to the line X in FIG. 4 following back-end-of-line (BEOL) interconnect formation and carrier wafer bonding, according to an embodiment of the invention.

FIG. 6B depicts a second cross-sectional view corresponding to the line Y1 in FIG. 4 following BEOL interconnect formation and carrier wafer bonding, according to an embodiment of the invention.

FIG. 6C depicts a third cross-sectional view corresponding to the line Y2 in FIG. 4 following BEOL interconnect formation and carrier wafer bonding, according to an embodiment of the invention.

FIG. 7A depicts a first cross-sectional view corresponding to the line X in FIG. 4 following wafer flipping and semiconductor substrate removal, according to an embodiment of the invention.

FIG. 7B depicts a second cross-sectional view corresponding to the line Y1 in FIG. 4 following wafer flipping and semiconductor substrate removal, according to an embodiment of the invention.

FIG. 7C depicts a third cross-sectional view corresponding to the line Y2 in FIG. 4 following wafer flipping and semiconductor substrate removal, according to an embodiment of the invention.

FIG. 8A depicts a first cross-sectional view corresponding to the line X in FIG. 4 following etch stop layer and substrate recessing, according to an embodiment of the invention.

FIG. 8B depicts a second cross-sectional view corresponding to the line Y1 in FIG. 4 following etch stop layer and substrate recessing, according to an embodiment of the invention.

FIG. 8C depicts a third cross-sectional view corresponding to the line Y2 in FIG. 4 following etch stop layer and substrate recessing, according to an embodiment of the invention.

FIG. 9A depicts a first cross-sectional view corresponding to the line X in FIG. 4 following backside cap layer formation and planarization, according to an embodiment of the invention.

FIG. 9B depicts a second cross-sectional view corresponding to the line Y1 in FIG. 4 following backside cap layer formation and planarization, according to an embodiment of the invention.

FIG. 9C depicts a third cross-sectional view corresponding to the line Y2 in FIG. 4 following backside cap layer formation and planarization, according to an embodiment of the invention.

FIG. 10A depicts a first cross-sectional view corresponding to the line X in FIG. 4 following gate cut patterning, according to an embodiment of the invention.

FIG. 10B depicts a second cross-sectional view corresponding to the line Y1 in FIG. 4 following gate cut patterning, according to an embodiment of the invention.

FIG. 10C depicts a third cross-sectional view corresponding to the line Y2 in FIG. 4 following gate cut patterning, according to an embodiment of the invention.

FIG. 11A depicts a first cross-sectional view corresponding to the line X in FIG. 4 following organic planarization layer (OPL) formation and etching, according to an embodiment of the invention.

FIG. 11B depicts a second cross-sectional view corresponding to the line Y1 in FIG. 4 following OPL formation and etching, according to an embodiment of the invention.

FIG. 11C depicts a third cross-sectional view corresponding to the line Y2 in FIG. 4 following OPL formation and etching, according to an embodiment of the invention.

FIG. 12A depicts a first cross-sectional view corresponding to the line X in FIG. 4 following spacer formation and etching, according to an embodiment of the invention.

FIG. 12B depicts a second cross-sectional view corresponding to the line Y1 in FIG. 4 following spacer formation and etching, according to an embodiment of the invention.

FIG. 12C depicts a third cross-sectional view corresponding to the line Y2 in FIG. 4 following spacer formation and etching, according to an embodiment of the invention.

FIG. 13A depicts a first cross-sectional view corresponding to the line X in FIG. 4 following OPL removal and dielectric liner layer deposition, according to an embodiment of the invention.

FIG. 13B depicts a second cross-sectional view corresponding to the line Y1 in FIG. 4 following OPL removal and dielectric liner layer deposition, according to an embodiment of the invention.

FIG. 13C depicts a third cross-sectional view corresponding to the line Y2 in FIG. 4 following OPL removal and dielectric liner layer deposition, according to an embodiment of the invention.

FIG. 14A depicts a first cross-sectional view corresponding to the line X in FIG. 4 following removal of part of the dielectric liner layer and backside cap layer removal, according to an embodiment of the invention.

FIG. 14B depicts a second cross-sectional view corresponding to the line Y1 in FIG. 4 following removal of part of the dielectric liner layer and backside cap layer removal, according to an embodiment of the invention.

FIG. 14C depicts a third cross-sectional view corresponding to the line Y2 in FIG. 4 following removal of part of the dielectric liner layer and backside cap layer removal, according to an embodiment of the invention.

FIG. 15 depicts a top view of a semiconductor structure with lines X, Y1 and Y2 on which the cross-sectional views of FIGS. 16A-21C are based, according to an embodiment of the invention.

FIG. 16A depicts a first cross-sectional view corresponding to the line X in FIG. 15 following remaining substrate removal and backside inter-layer dielectric (ILD) layer formation and planarization, according to an embodiment of the invention.

FIG. 16B depicts a second cross-sectional view corresponding to the line Y1 in FIG. 15 following remaining substrate removal and backside ILD layer formation and planarization, according to an embodiment of the invention.

FIG. 16C depicts a third cross-sectional view corresponding to the line Y2 in FIG. 15 following remaining substrate removal and backside ILD layer formation and planarization, according to an embodiment of the invention.

FIG. 17A depicts a first cross-sectional view corresponding to the line X in FIG. 15 following backside ILD layer patterning for backside contacts, according to an embodiment of the invention.

FIG. 17B depicts a second cross-sectional view corresponding to the line Y1 in FIG. 15 following backside ILD layer patterning for backside contacts, according to an embodiment of the invention.

FIG. 17C depicts a third cross-sectional view corresponding to the line Y2 in FIG. 15 following backside ILD layer patterning for backside contacts, according to an embodiment of the invention.

FIG. 18A depicts a first cross-sectional view corresponding to the line X in FIG. 15 following placeholder layer removal and source/drain region gouging, according to an embodiment of the invention.

FIG. 18B depicts a second cross-sectional view corresponding to the line Y1 in FIG. 15 following placeholder layer removal and source/drain region gouging, according to an embodiment of the invention.

FIG. 18C depicts a third cross-sectional view corresponding to the line Y2 in FIG. 15 following placeholder layer removal and source/drain region gouging, according to an embodiment of the invention.

FIG. 19A depicts a first cross-sectional view corresponding to the line X in FIG. 15 following backside contact formation, according to an embodiment of the invention.

FIG. 19B depicts a second cross-sectional view corresponding to the line Y1 in FIG. 15 following backside contact formation, according to an embodiment of the invention.

FIG. 19C depicts a third cross-sectional view corresponding to the line Y2 in FIG. 15 following backside contact formation, according to an embodiment of the invention.

FIG. 20A depicts a first cross-sectional view corresponding to the line X in FIG. 15 following backside power rail and backside power delivery network (BSPDN) formation, according to an embodiment of the invention.

FIG. 20B depicts a second cross-sectional view corresponding to the line Y1 in FIG. 15 following backside power rail and BSPDN formation, according to an embodiment of the invention.

FIG. 20C depicts a third cross-sectional view corresponding to the line Y2 in FIG. 15 following backside power rail and BSPDN formation, according to an embodiment of the invention.

### DETAILED DESCRIPTION

Illustrative embodiments of the invention may be described herein in the context of illustrative methods for forming a gate cut structure including an airgap, along with illustrative apparatus, systems and devices formed using such methods. However, it is to be understood that embodiments of the invention are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although embodiments of the present invention are discussed in connection with nanosheet stacks, the embodiments of the present invention are not necessarily limited thereto, and may similarly apply to nanowire stacks.

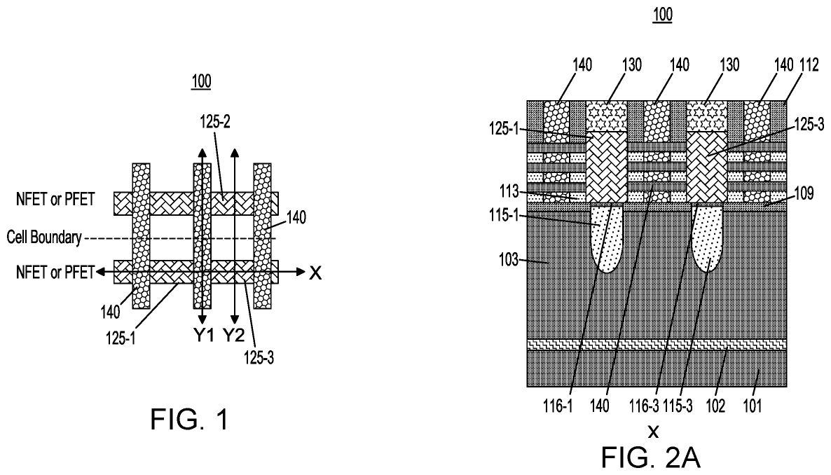

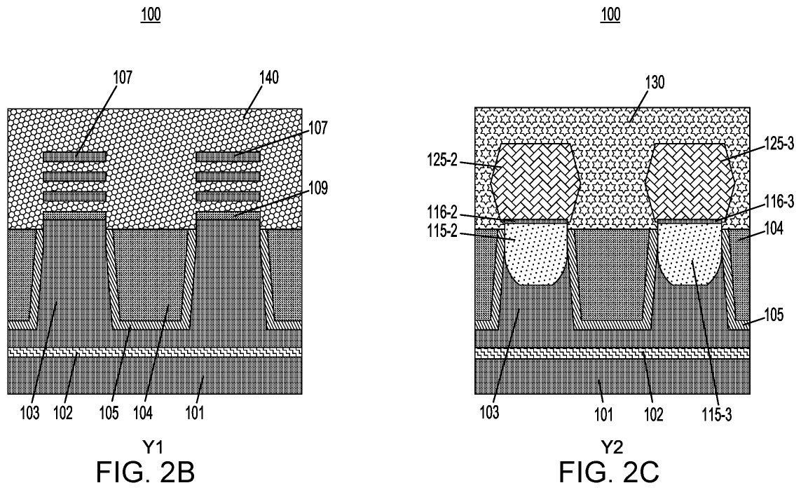

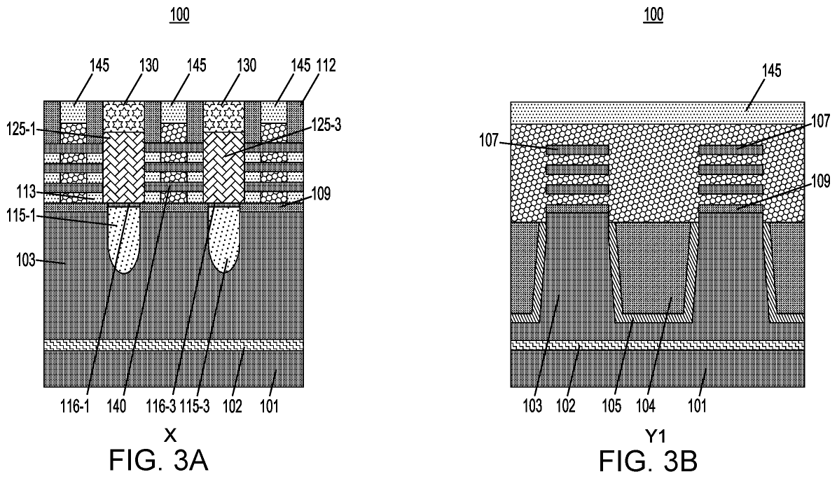

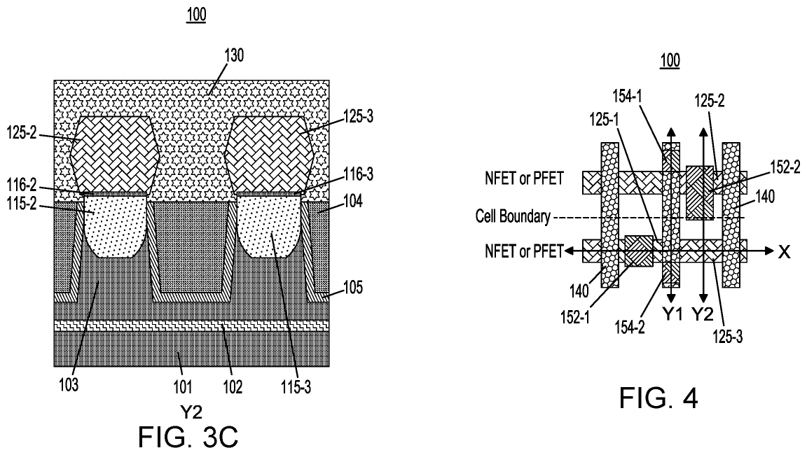

FIG. 1 depicts a top view of a semiconductor structure 100 with lines X, Y1 and Y2 on which the cross-sectional views of FIGS. 2A-3C are based. FIG. 1 illustrates gate structures 140 and source/drain regions 125-1, 125-2 and 125-3 (collectively “source/drain regions 125”), which are described in more detail herein in connection with, for example, FIGS. 2A-3C. Referring to FIG. 1 and to the cross-sectional views in FIGS. 2A, 2B and 2C, which respectively correspond to the lines X, Y1 and Y2 in FIG. 1, a semiconductor structure 100 includes a stacked structure of channel layers 107 and gate structures 140. In an illustrative embodiment, the channel layers 107 comprise silicon. In an illustrative embodiment, the gate structures 140 are formed after a replacement metal gate (RMG) process in which sacrificial layers are removed and replaced with the gate structures 140.

In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as, for example, tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

Gate spacers 112 are formed on sides of the gate structures 140. The spacer material can comprise for example, one or more dielectrics, including, but not necessarily limited to, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), silicon oxide (SiOx) (where x is for example, 2, 1.99 or 2.01) and combinations thereof. The gate spacers 112 can be formed by any suitable techniques such as deposition followed by directional etching. Deposition may include but is not limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD). Directional etching may include but is not limited to, reactive ion etching (RIE).

Inner spacers 113 are disposed on opposite sides of lower gate structures 140 under and/or over end portions of the channel layers 107. The material of the inner spacers 113 can comprise, but is not necessarily limited to, a nitride, such as, SiN, SiON, SiCN, BN, SiBN, SiBCN or SiOCN. In an illustrative embodiment, the gate spacers 112 are formed from the same or similar material to that of the inner spacers 113. Like the gate spacers 112, the inner spacers 113 can be formed by any suitable techniques such as deposition followed by directional etching.

Lowermost gate structures 140 of the nanosheet stacks are formed on bottom dielectric isolation (BDI) layers 109, which may comprise, for example, silicon oxide SiOx, silicon oxycarbide (SiOC), SiN, SION, SiCN, BN, SiBCN, SiOCN or some other dielectric. The BDI layers 109 are under bottom surfaces of the lowermost gate structures 140.

First and second semiconductor substrates 101 and 103 comprise semiconductor material including, but not limited to, silicon (Si), III-V. II-V compound semiconductor materials or other like semiconductor materials. In addition, multiple layers of the semiconductor materials can be used as the semiconductor material of the first and second semiconductor substrates 101 and 103. An etch stop layer 102 is formed on the first semiconductor substrate 101, and may comprise, for example, SiOx, or silicon germanium (SiGe). In illustrative embodiments, the etch stop layer 102 comprises a germanium concentration of about 25% (e.g., SiGe25), but the embodiments are not necessarily limited to SiGe25 for the etch stop layer 102. The second semiconductor substrate 103 comprising, for example, the same semiconductor material as the first semiconductor substrate 101, or other like semiconductor material, is formed on the etch stop layer 102.

Isolation regions (e.g., shallow trench isolation (STI)) regions comprising a fill portion 104 and a liner portion 105 are formed in the second semiconductor substrate 103 between nanosheet stacks comprising channel layers 107 and gate structures 140 and between source/drain regions 125. In illustrative embodiments, the fill portion comprises an oxide (e.g., SiOx) and the liner portion 105 comprises a nitride (e.g., SiN, SiON, SiCN, BN, SiBCN, SiOCN). The isolation regions fill in the recessed portions of the second semiconductor substrate 103.

Prior to epitaxial growth of the source/drain regions 125, placeholder semiconductor layers 115-1, 115-2 and 115-3 (collectively “placeholder semiconductor layers 115”) and buffer semiconductor layers 116-1, 116-2 and 116-3 (collectively “buffer semiconductor layers 116”) are formed between the nanosheet stacks under areas where the source/drain regions 125 to be formed. An etching process such as, for example, RIE, is performed on exposed portions of the BDI layer 109 and underlying portions of the second semiconductor substrate 103 between the nanosheet stacks to form openings (e.g., trenches) in the second semiconductor substrate 103. The openings are formed by etching through parts of the BDI layer 109 and parts of the second semiconductor substrate 103 and comprise a U-shape.

In illustrative embodiments, the placeholder semiconductor layers 115 comprise, for example, SiGe, III-V semiconductor material or other semiconductor material, and the buffer semiconductor layers 116 comprise, for example, silicon or other semiconductor material. The placeholder semiconductor layers 115 and buffer semiconductor layers 116 are epitaxially grown. The buffer semiconductor layers 116 are epitaxially grown from the exposed surfaces of their corresponding placeholder semiconductor layers 115. In more detail, the buffer semiconductor layers 116 are grown from top surfaces of the placeholder semiconductor layers 115.

The source/drain regions 125 are epitaxially grown between the nanosheet stacks. The source/drain regions 125 comprise epitaxial layers grown from sides of channel layers 107, as well as from the top surfaces of the buffer semiconductor layers 116. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The epitaxial deposition process may employ the deposition chamber of a chemical vapor deposition type apparatus, such as a metal-organic chemical vapor deposition (MOCVD), rapid thermal chemical vapor deposition (RTCVD), ultra-high vacuum chemical vapor deposition (UHVCVD), or a low pressure chemical vapor deposition (LPCVD) apparatus. A number of different sources may be used for the epitaxial deposition of the in situ doped semiconductor material. In some embodiments, the gas source for the deposition of an epitaxially formed semiconductor material may include silicon (Si) deposited from silane, disilane, trisilane, tetrasilane, hexachlorodisilane, tetrachlorosilane, dichlorosilane, trichlorosilane, and combinations thereof. In other examples, when the semiconductor material includes germanium, a germanium gas source may be selected from the group consisting of germane, digermane, halogermane, dichlorogermane, trichlorogermane, tetrachlorogermane and combinations thereof. The temperature for epitaxial deposition typically ranges from 450° C. to 900° C. Although higher temperature typically results in faster deposition, the faster deposition may result in crystal defects and film cracking.

An inter-layer dielectric (ILD) layer 130 fills in portions on and around the source/drain regions 125. The ILD layer 130 is deposited using deposition techniques such as, for example, CVD, PECVD, RFCVD, PVD, ALD, MBD, PLD, and/or LSMCD, followed by a planarization process, such as, CMP. The ILD layer 130 may comprise, for example, SiOx, SiOC, SiOCN or some other dielectric material.

In a non-limiting illustrative embodiment, a height of the channel layers 107 and lower gate structures 140 (under the uppermost channel layer 107) can be in the range of about 6 nm to about 15 nm depending on the application of the device. In accordance with an embodiment of the present invention, each of the channel layers 107 has the same or substantially the same composition and size as each other, each of the gate structures 140 has the same or substantially the same composition as each other and each of the lower gate structures 140 has the same size as each other.

As used herein, “frontside or “first side” refers to a side on top of the first and second semiconductor substrates 101 and 103 and/or in front of, on top of or in an upward direction from the stacked nanosheet/gate and channel layers of the transistors in the orientation shown in the cross-sectional figures. As used herein, “backside” or “second side” refers to a side below the first and/or second semiconductor substrates 101 and 103 and/or behind, below or in a downward direction from the stacked nanosheet/gate and channel layers of the transistors in the orientation shown in the cross-sectional figures (e.g., opposite the “frontside”).

Referring to FIGS. 3A-3C, the uppermost gate structures 140 of the nanosheet stacks comprising the channel layers 107 and gate structures 140 are recessed. The uppermost gate structures 140 are recessed in an etching process using, for example, RIE. A frontside cap layer 145 comprising dielectric material is deposited on the recessed gate structures 140 using deposition techniques such as, for example, CVD, PECVD, RFCVD, PVD, ALD, MBD, PLD, and/or LSMCD, followed by a planarization process, such as, chemical mechanical planarization (CMP) to remove excess portions of the dielectric material deposited on top of the recessed gate structures 140. The dielectric material of the frontside cap layer 145 may comprise, but is not necessarily limited to, SiN, SiC, SION, SiOC, SiCN, BN, SiBN, SiBCN, SiOCN, SiOx or some other dielectric.

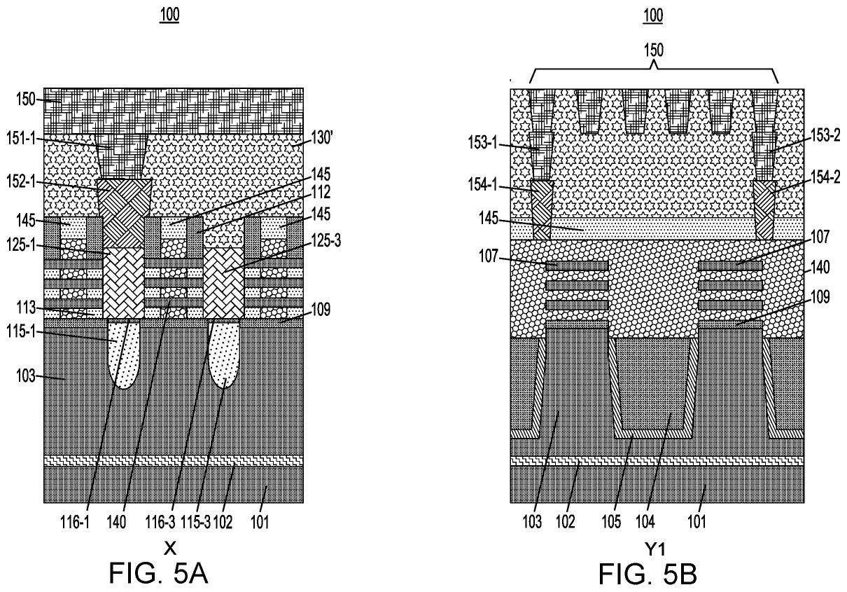

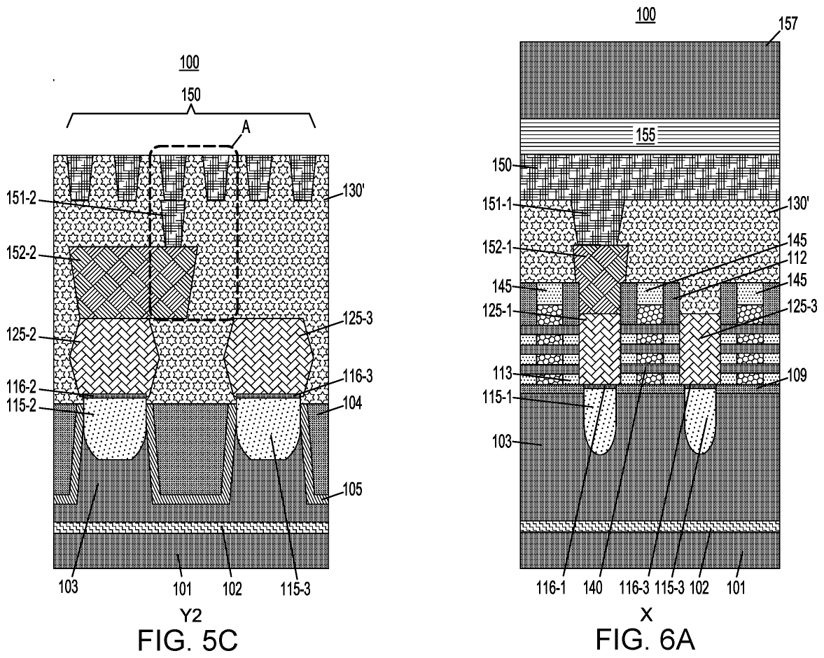

FIG. 4 depicts a top view of a semiconductor structure with lines X, Y1 and Y2 on which the cross-sectional views of FIGS. 5A-14C are based. In addition to what is shown is FIG. 1, FIG. 4 further illustrates frontside source/drain contacts 152-1 and 152-2 and frontside gate contacts 154-1 and 154-2. Referring to FIGS. 4 and 5A-5C, additional ILD material is deposited to form an additional ILD layer 130′ on top of the ILD layer 130. Then, frontside source/drain contacts 152-1 and 152-2 are formed in the ILD layers 130 and 130′ to contact the source/drain regions 125-1 and 125-2, respectively. In forming the frontside source/drain contacts 152-1 and 152-2, openings are formed through portions of the ILD layers 130 and 130′. The openings expose portions the source/drain regions 125-1 and 125-2 on which the frontside source/drain contacts 152-1 and 152-2 are to be formed. According to an embodiment, masks are formed on parts of the additional ILD layer 130′, and exposed portions of the ILD layers 130 and 130′ corresponding to where the openings are to be formed are removed using, for example, a dry etching process using a RIE or ion beam etch (IBE) process, a wet chemical etch process or a combination of these etching processes. A dry etch may be performed using a plasma. Such wet or dry etch processes include, for example, IBE by Ar/CHF3 based chemistry.

Metal layers are deposited in the openings to form the frontside source/drain contacts 152-1 and 152-2. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as, CMP to remove excess portions of the metal layers from on top of the additional ILD layer 130′.

The frontside source/drain contacts 152-1 and 152-2 contact respective ones of the source/drain regions 125-1 and 125-2. The frontside source/drain contacts 152-1 and 152-2 extend through the ILD layers 130 and 130′ to land on and contact the corresponding source/drain regions 125-1 and 125-2.

Frontside gate contacts 154-1 and 154-2 are formed through the additional ILD layer 130′ to land on and contact a corresponding gate structure 140 (may also be referred to as a gate region). The process and materials used for forming the frontside gate contacts 154-1 and 154-2 are similar to those used for forming the frontside source/drain contacts 152-1 and 152-2. Middle-of-line (MOL) metallization layers 150 are formed in the additional ILD layer 130′. Vias 151-1 and 151-2 extending from the MOL metallization layers 150 to frontside source/drain contacts 152-1 and 152-2, respectively, are also formed in the additional ILD layer 130′. Vias 153-1 and 153-2 extending from the MOL metallization layers 150 to frontside gate contacts 154-1 and 154-1, respectively, are further formed in the additional ILD layer 130′. The process and materials used for forming the MOL metallization layers 150 and the vias 151-1, 151-2, 153-1 and 153-2 are similar to those used for forming the frontside source/drain contacts 152-1 and 152-2, and the frontside gate contacts 154-1 and 154-2. As can be seen in FIGS. 4 and 5C, the frontside source/drain contact 152-2 extends into a cell boundary area A to connect to signal wires that are at or beyond a cell boundary area A.

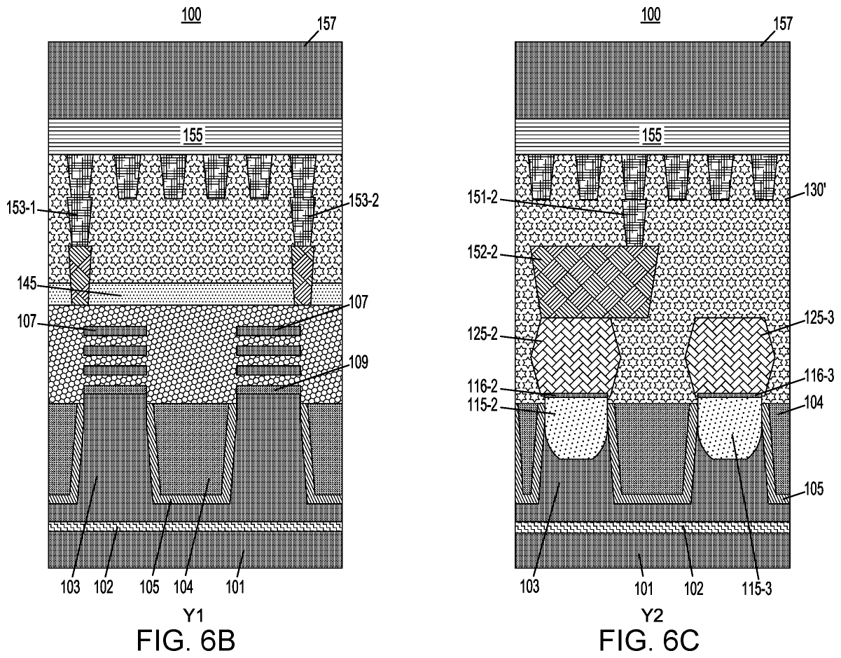

Referring to FIGS. 6A-6C, frontside BEOL interconnects 155 are formed on the additional ILD layer 130′ including the MOL metallization layers 150. As can be seen, the MOL metallization layers 150 contact the frontside BEOL interconnects 155. A carrier wafer 157 is bonded to the frontside BEOL interconnects 155. The frontside BEOL interconnects 155 include various BEOL interconnect structures which may electrically connect to the MOL metallization layers 150. The carrier wafer 157 may be formed of materials similar to that of the first and second semiconductor substrates 101 and 103, and may be formed over the frontside BEOL interconnects 155 using a wafer bonding process, such as dielectric-to-dielectric bonding.

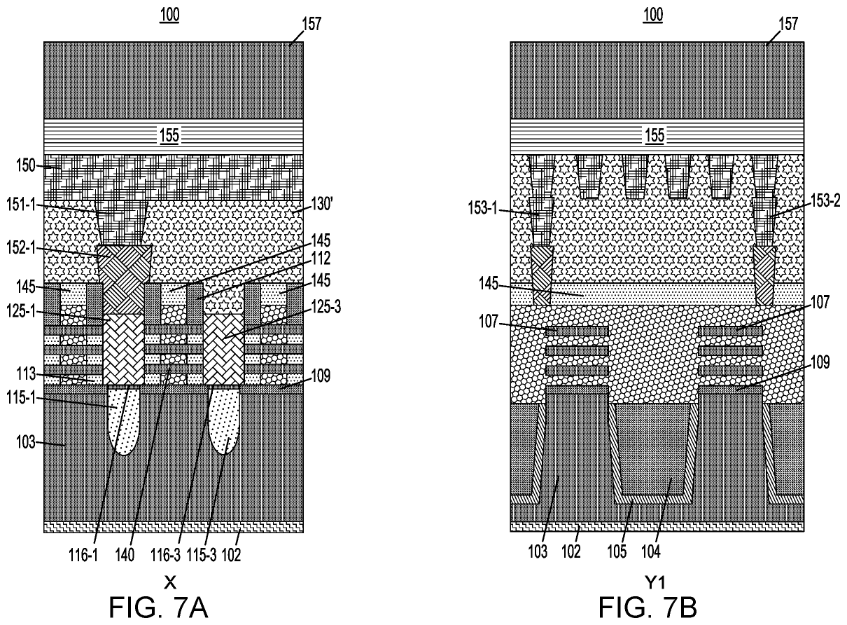

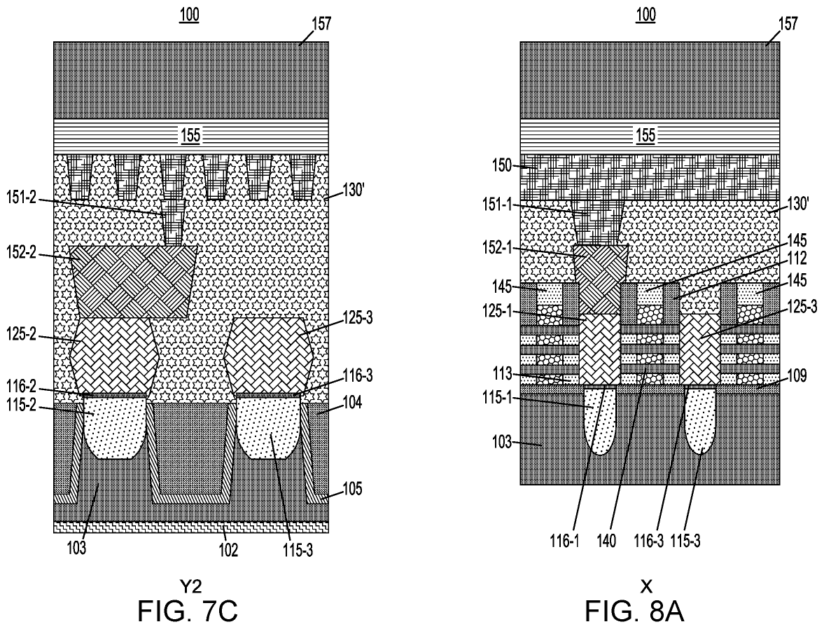

Referring to FIGS. 7A-7C, using the carrier wafer 157, the semiconductor structure 100 may be “flipped” (e.g., rotated 180 degrees) so that the structure is inverted. In addition, the first semiconductor substrate 101 is removed from the backside of the semiconductor structure 100. The removal process, which comprises etching of the first semiconductor substrate 101, stops at the etch stop layer 102. For example, the first semiconductor substrate 101 is selectively etched with an etchant that selectively etches silicon with respect to a material of the etch stop layer 102 (e.g., SiGe).

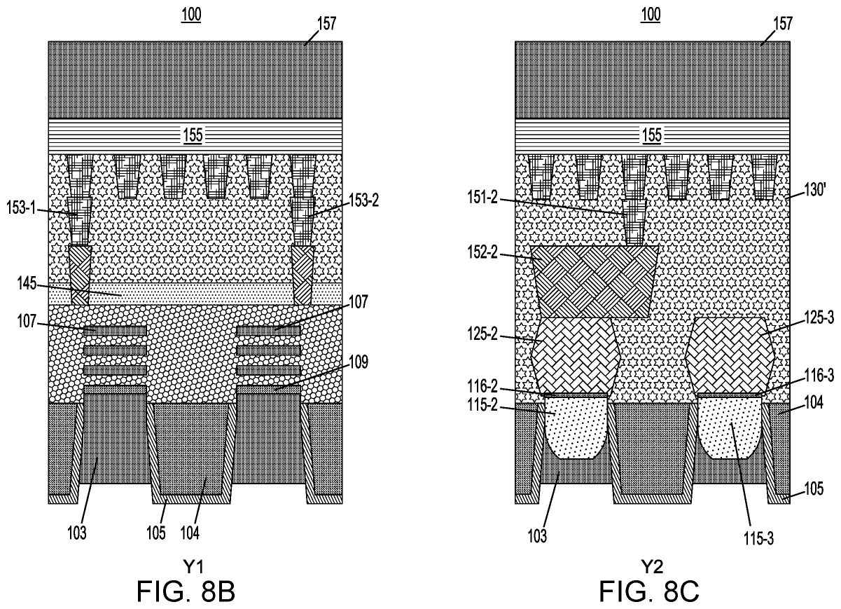

Referring to FIGS. 8A-8C, the etch stop layer 102 is removed. An exposed portion of the second semiconductor substrate 103 (e.g., silicon layer) is selectively etched to recess the second semiconductor substrate 103 with respect to the isolation regions comprising the fill and liner portions 104 and 105. The etch stop layer 102 is removed, followed by recessing of the second semiconductor substrate 103. Etching processes for removal of the etch stop layer 102 include, for example, IBE by Ar/CHF3 based chemistry. Etchants for recessing of the second semiconductor substrate 103 include, for example, potassium hydroxide (KOH) and tetramethylammonium hydroxide (TMAH).

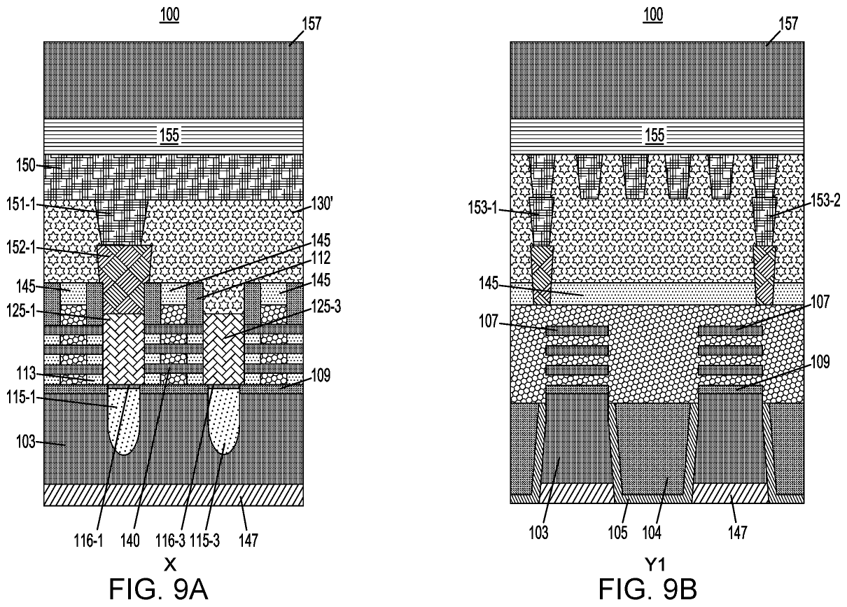

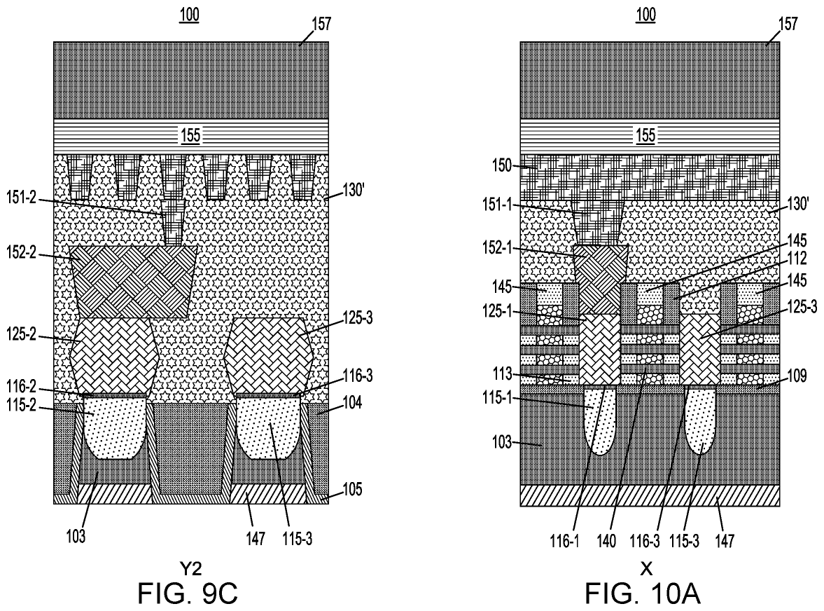

Referring to FIGS. 9A-9C, a backside cap layer 147 comprising dielectric material is deposited on the recessed second semiconductor substrate 103 using deposition techniques such as, for example, CVD, PECVD, RFCVD, PVD, ALD, MBD, PLD, and/or LSMCD, followed by a planarization process, such as, chemical mechanical planarization (CMP) to remove excess portions of the dielectric material deposited on top of the isolation regions. In illustrative embodiments, the outer surface of the backside cap layer 147 is co-planar with the outer surfaces of the liner portions 105 of the isolation regions. The dielectric material of the backside cap layer 147 may comprise, but is not necessarily limited to, SiN, SiC, SiON, SiOC, SiCN, BN, SiBN, SiBCN, SiOCN, SiOx or some other dielectric.

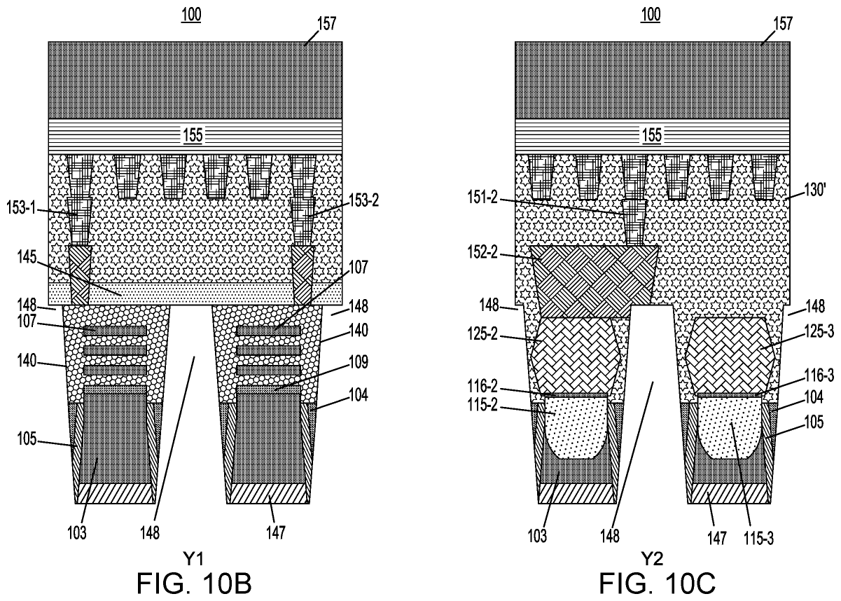

Referring to FIGS. 10A-10C, portions of the isolation regions, gate structures 140 and the ILD layer 130 are removed to create openings 148 where gate cut portions will be formed. The removal of the portions of the isolation regions, gate structures 140 and the ILD layer 130 can be performed using etch processes such as, for example, RIE using the gas NF₃, BCl₃, Cl₂, CHF₃, CF₄ and/or argon. As can be seen in FIG. 10B, the etching stops at the frontside cap layer 145. The presence of the frontside cap layer 145 prevents the gate cut portion, which is formed from the backside of semiconductor structure 100, from being too deep. As a result, as shown in FIG. 10C, a small corner portion of the frontside source/drain contact 152-2 is removed when the openings 148 are formed instead of removing a larger portion of the frontside source/drain contact 152-2 if the frontside cap layer 145 was not present. As can be seen in FIG. 10B, the middle opening 148 cuts the gate structures 140 into two separated gate regions on either side of the middle opening 148. In addition, the middle opening 148 in FIG. 10C, which corresponds to the middle opening 148 in FIG. 10B, is disposed between two source/drain regions 125-2 and 125-3.

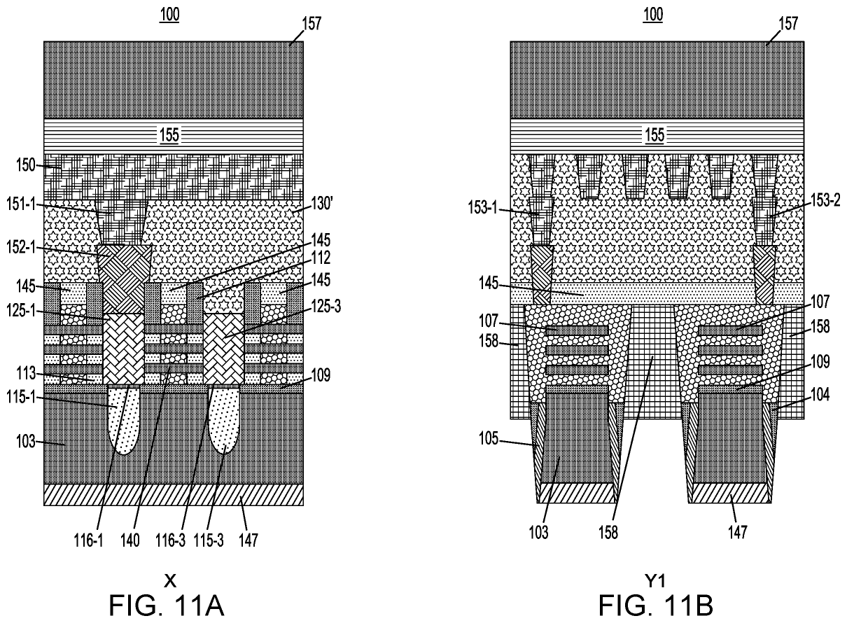

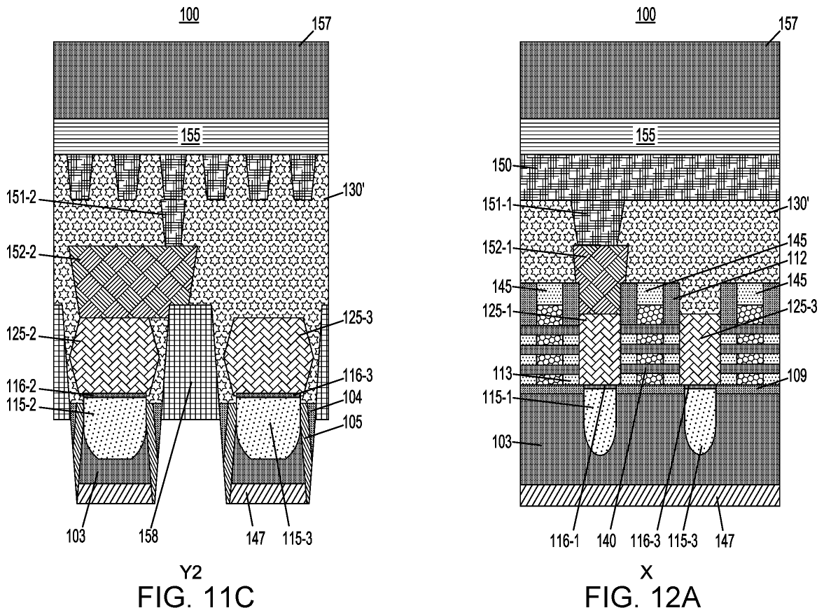

Referring to FIGS. 11A-11C, an organic planarization layer (OPL) 158 is deposited in each of the openings 148 and etched back to recess the OPLs 158. The OPLs 158 comprise, but are not necessarily limited to, an organic polymer including C. H, and N. In an embodiment, the OPL material can be free of silicon (Si). According to an embodiment, the OPL material can be free of Si and fluorine (F). As defined herein, a material is free of an atomic element when the level of the atomic element in the material is at or below a trace level detectable with analytic methods available in the art. Non-limiting examples of the OPL material include JSR HM8006, JSR HM8014, AZ UM10M2, Shin Etsu ODL-102, or other similar commercially available materials from such vendors as JSR, TOK, Sumitomo, Rohm & Haas, etc. The OPLs 158 can be deposited, for example, by spin coating.

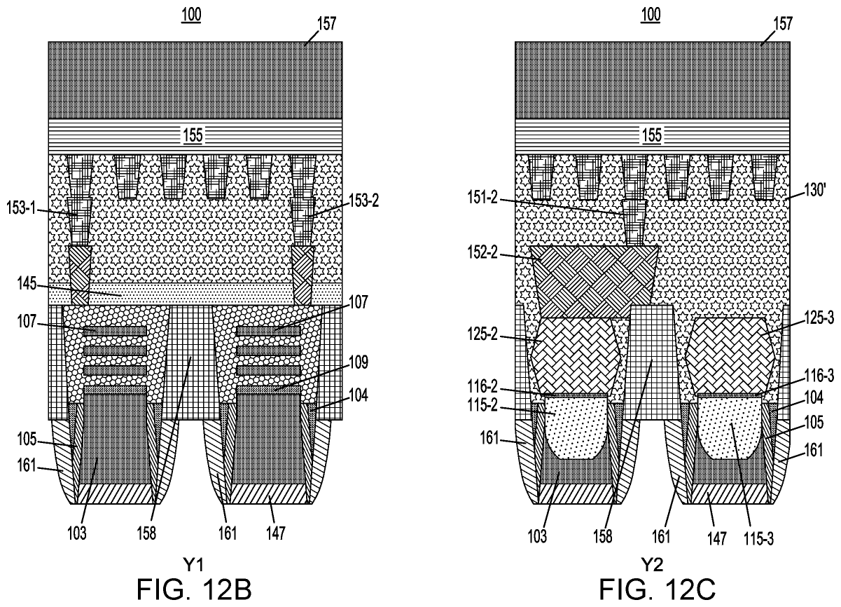

Referring to FIGS. 12A-12C, backside spacers 161 are formed on the OPLs 158 and on sides of the isolation regions including sides of the remaining fill portions 104 and liner portions 105, and on sides of the backside cap layers 147. The spacer material can comprise for example, one or more dielectrics, including, but not necessarily limited to, SiN, SiON, SiCN, BN, SiBN, SiBCN, SiOCN and combinations thereof. The backside spacers 161 can be formed by any suitable techniques such as low temperature deposition followed by directional etching. According to an illustrative embodiment, the low temperature deposition is performed with organosilicon-related materials, silane and/or NH₃-related chemicals, and is performed at a temperature in the range of about 50° C. to about 300° C. Directional etching may include, but is not limited to, RIE.

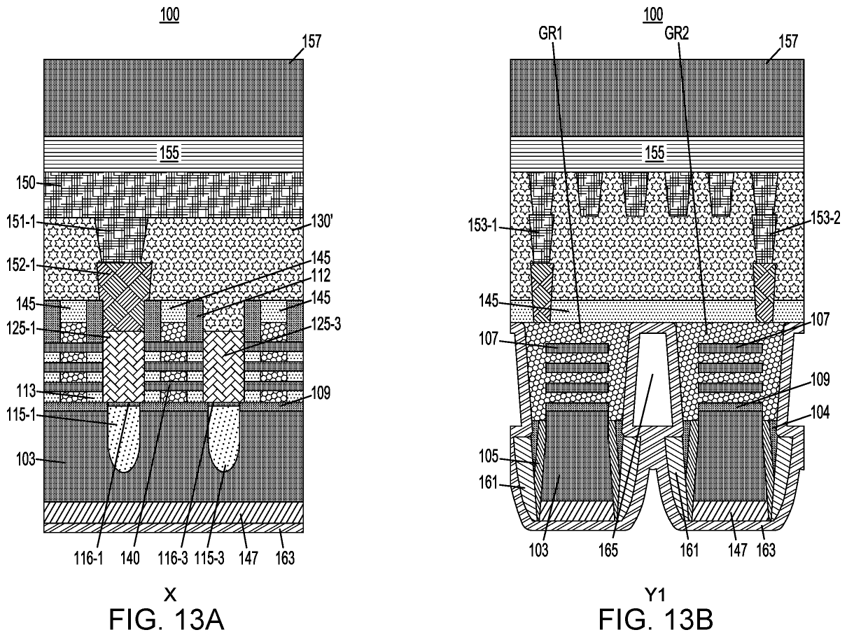

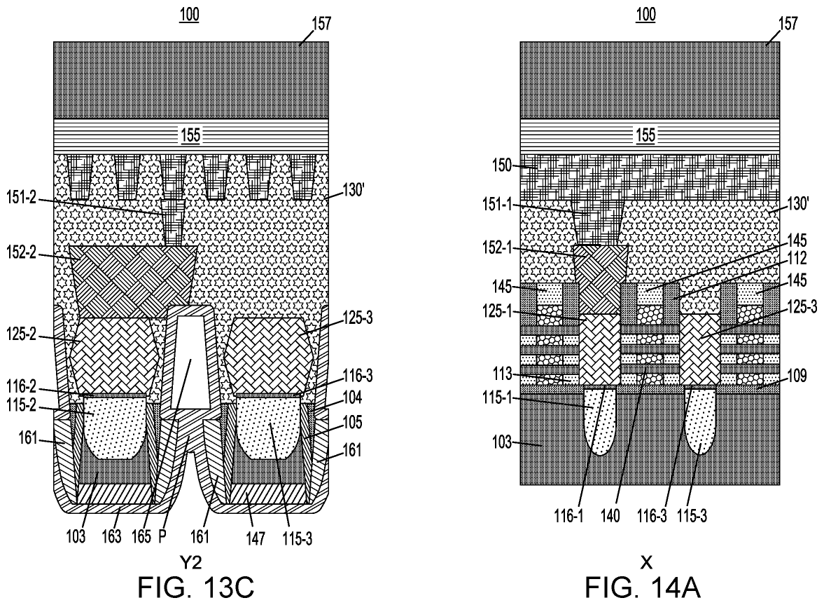

Referring to FIGS. 13A-13C, the OPLs 158 are removed using, for example, an ashing process, and a dielectric liner layer 163 is conformally deposited on exposed surfaces of the backside cap layer 147, on exposed surfaces of the gate structures 140, the frontside cap layer 145, the fill portions 104, the ILD layer 130 and the frontside source/drain contact 152-2 left after the removal of the OPLs 158, and on the exposed surfaces of the backside spacers 161. The conformal nature of the deposition of the dielectric liner layer 163 results in a pinched-off portion P of the dielectric liner layer 163, which fills in an area between backside spacers 161. As can be seen, once the deposition of the dielectric liner layer 163 ceases, a gate cut portion (also referred to herein as an isolation structure) comprising the dielectric liner layer 163 enclosing a vacant area 165 is formed. In illustrative embodiments, the vacant area 165 comprises air and may also be referred to herein as an “airgap.” The vacant area 165 reduces capacitance between gates of two transistors (e.g., nanosheet FETs). The conformal deposition can be performed using, for example, ALD or CVD. The material of the dielectric liner layer 163 comprises, for example, SiN, SiON, SiCN, BN, SiBN, SiBCN, SiOCN and combinations thereof.

The gate cut portion comprising the dielectric liner layer 163 enclosing a vacant area 165 is disposed between a first gate region GR1 and a second gate region GR2 (e.g., the two portions of the gate structures 140 formed when the middle opening 148 was formed), and isolates the first gate region GR1 from the second gate region GR2. The first gate region GR1 and the second gate region GR2 contact the dielectric liner layer 163 of the gate cut portion. The gate cut portion is further disposed between a first source/drain region and a second source/drain region (e.g., between source/drain region 125-2 and source/drain region 125-3). Part of the gate cut portion contacts the frontside source/drain contact 152-2. The frontside source/drain contact 152-2 is disposed on a first side (frontside) of the source/drain region 125-2 and the placeholder semiconductor layer 115-2 is disposed on a second side (backside) of the source/drain region 125-2 opposite the first side.

As can be seen in FIGS. 13B and 13C, a lower part of the gate cut portion including the pinched-off portion P is disposed in an isolation region (e.g., between remaining fill portions 104). The backside spacers 161 are disposed between the isolation region and the lower part of the gate cut portion. The frontside cap layer 145 is disposed on the first gate region GR1, the second gate region GR2 and the gate cut portion. The frontside cap layer 145 contacts the first gate region GR1, the second gate region GR2 and the gate cut portion.

The first and second gate regions GR1 and GR2 include a first and second plurality of gate structures 140, respectively. A first nanosheet structure comprises the first gate region GR1 including the first plurality of gate structures 140, and a first plurality of channel layers 107 alternately stacked with the first plurality of gate structures 140. A second nanosheet structure comprises a second gate region GR2 including a second plurality of gate structures 140, and a second plurality of channel layers 107 alternately stacked with the second plurality of gate structures 140.

A first source/drain region (e.g., source/drain region 125-2) is disposed on a side of the first nanosheet structure, and a second source/drain region (e.g., source/drain region 125-3) is disposed on a side of the second nanosheet structure. The gate cut portion is disposed between the first source/drain region and the second source/drain region.

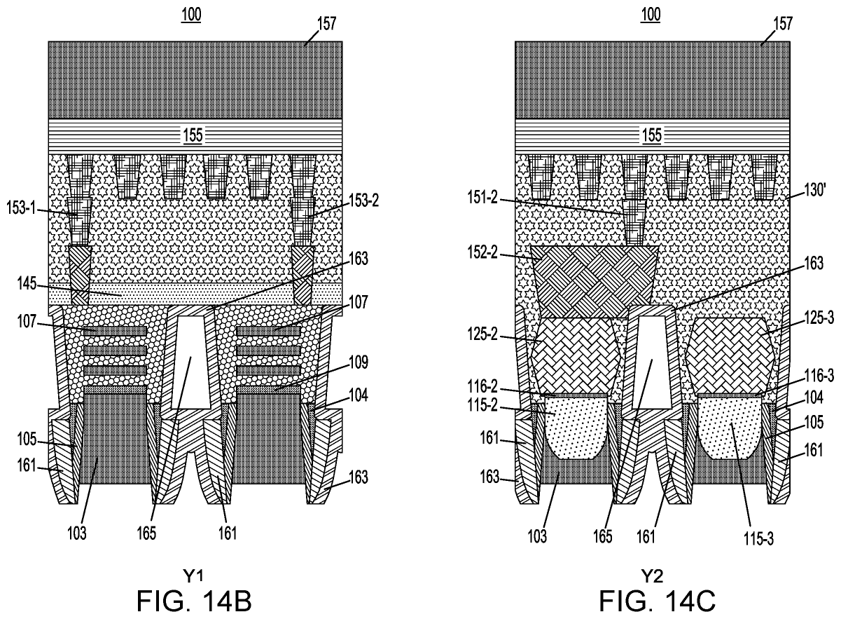

Referring to FIGS. 14A-14C, portions of the dielectric liner layer 163 on the backside cap layers 147 are removed to expose the backside cap layers 147, and the backside cap layers 147 are selectively removed with respect to the liner portions 105 of the isolation regions and the remaining portions of the dielectric liner layer 163 and the backside spacers 161. The selective removal of the backside cap layers 147 can be performed using, for example, diluted HF for a wet etch process, and CF₄/CHF₃ for a RIE process. The removal of the backside cap layers 147 exposes the underlying second semiconductor substrate 103.

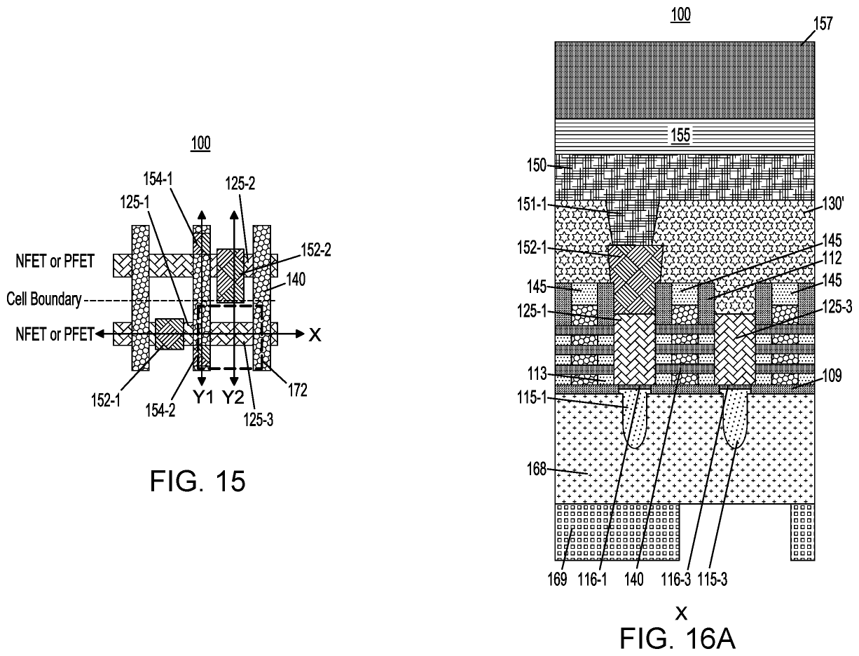

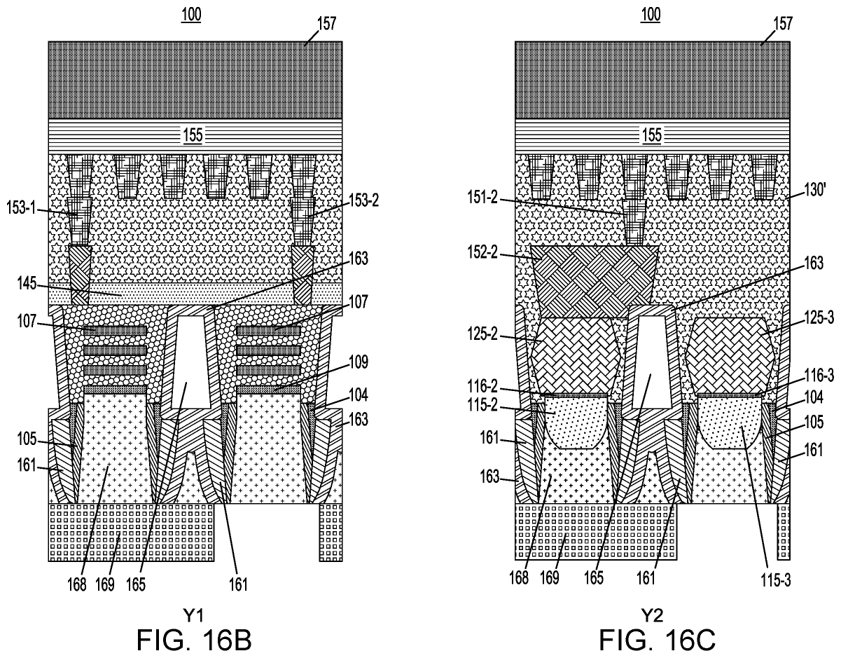

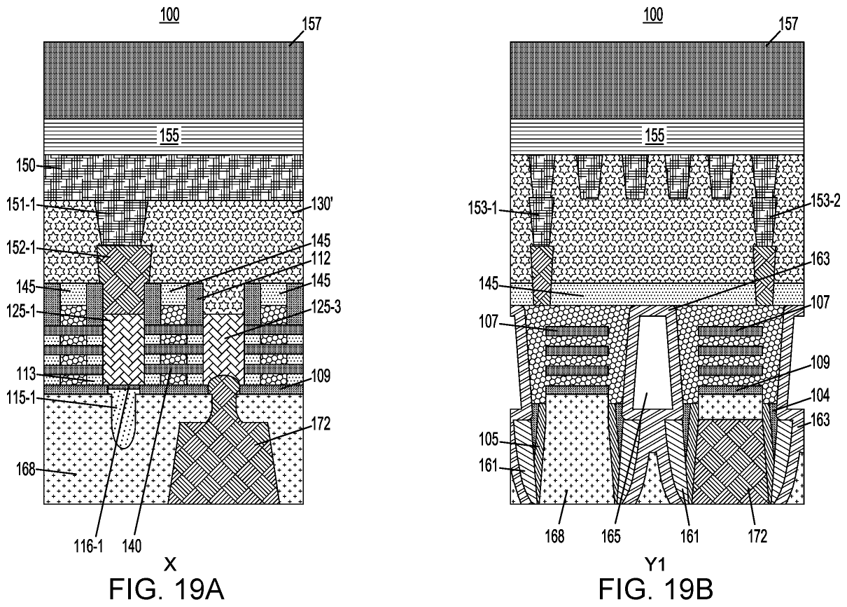

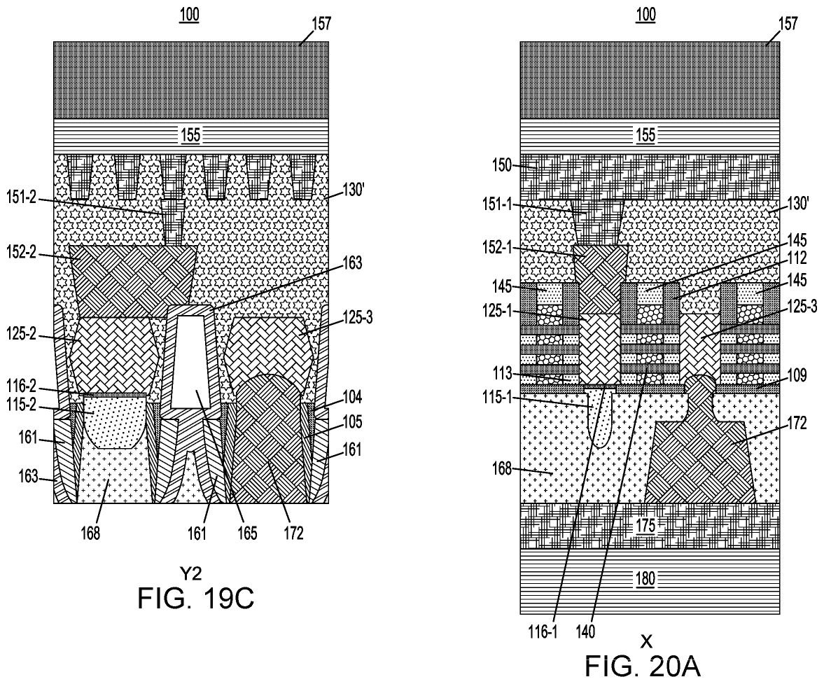

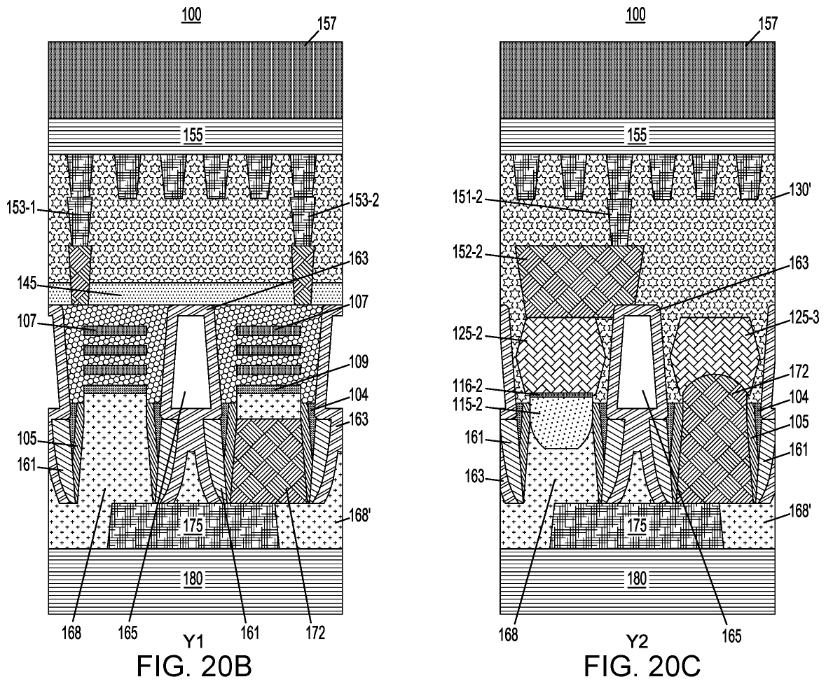

FIG. 15 depicts a top view of a semiconductor structure with lines X, Y1 and Y2 on which the cross-sectional views of FIGS. 16A-20C are based. In addition to what is shown is FIG. 4, FIG. 15 further illustrates a backside source/drain contact 172 described in more detail in connection with FIGS. 19A-20C. Referring to FIGS. 15 and 16A-16C, the second semiconductor substrate 103 is selectively removed from the semiconductor structure 100 with respect to the remaining portions of the isolation regions (e.g., fill and liner portions 104 and 105 of STI regions), BDI layers 109, placeholder semiconductor layers 115, backside spacers 161 and dielectric liner layer 163. Etching processes for removal of the second semiconductor substrate 103 include, for example, IBE by Ar/CHF₃ based chemistry.

A backside ILD layer 168 is deposited to fill in areas formerly occupied by the second semiconductor substrate 103 and the backside cap layer 147. The backside ILD layer 168 is deposited using deposition techniques such as, for example, CVD, PECVD, RFCVD, PVD, ALD, MBD. PLD, and/or LSMCD, followed by a planarization process, such as, CMP to cause the backside ILD layer 168 to be coplanar with outer surfaces of the backside spacers 161 and dielectric liner layer 163. The backside ILD layer 168 may comprise, for example, SiOx, SiOC, SiOCN or some other dielectric. A mask 169 with an opening where a backside source/drain contact is to be formed is deposited on the planarized surface.

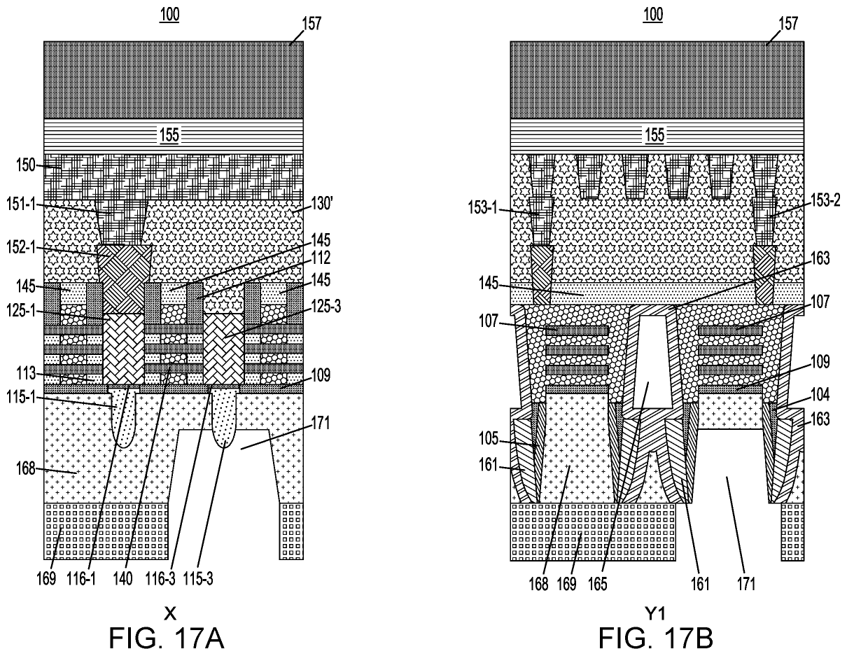

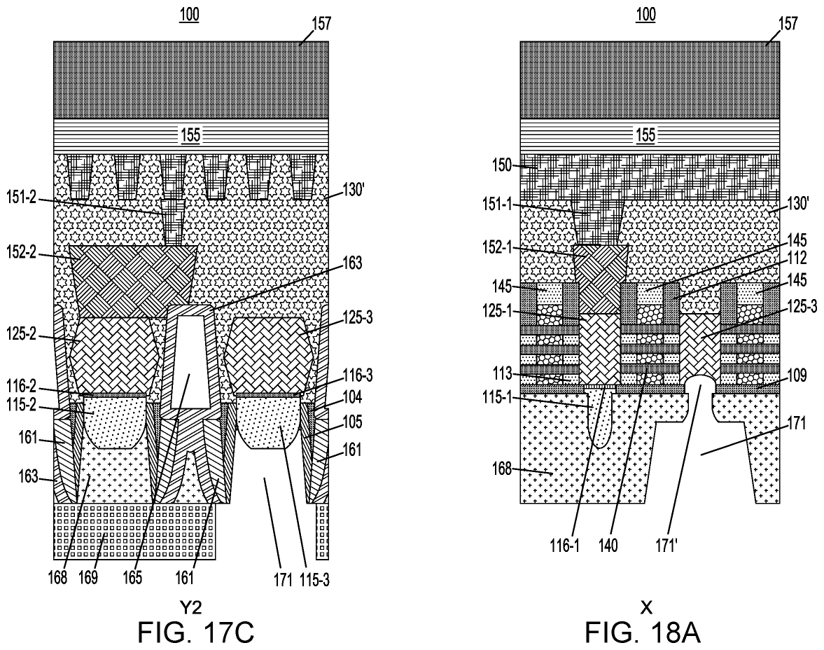

Referring to FIGS. 17A-17C, exposed portions of the backside ILD layer 168 are removed through the opening in the mask 169 to create opening 171 in the backside ILD layer 168. The exposed portions of the backside ILD layer 168 are removed using, for example, a dry etching process using a RIE or IBE process, a wet chemical etching process or a combination of these etching processes. A dry etch may be performed using a plasma. Such wet or dry etch processes include, for example, IBE by Ar/CHF₃ based chemistry.

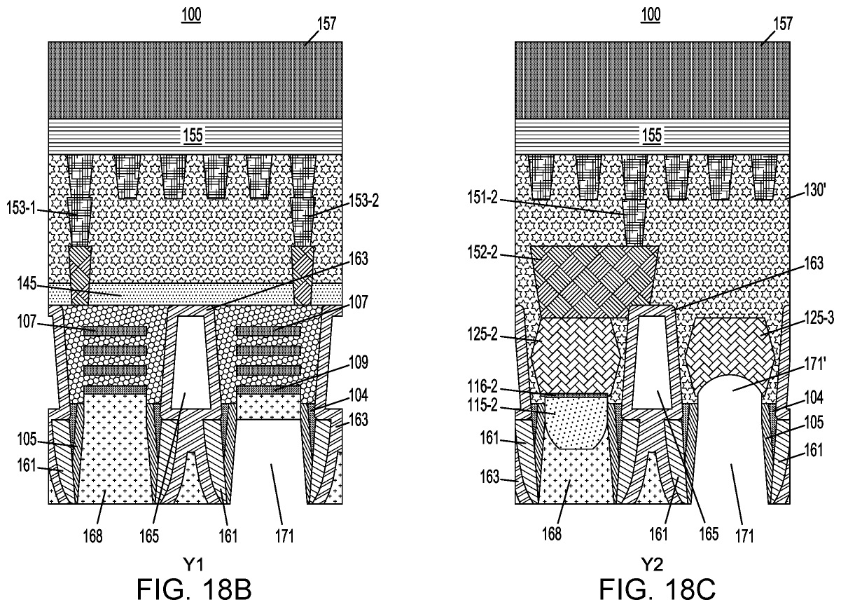

Referring to FIGS. 18A-18C, the placeholder semiconductor layer 115-3 and corresponding buffer semiconductor layer 116-3 are selectively removed to expose backside portions of the source/drain region 125-3. In creating opening 171′ caused by the removal of the placeholder semiconductor layer 115-3 and corresponding buffer semiconductor layer 116-3, the backside portion of the source/drain region 125-3 is optionally gouged to create an arc-like shape in the backside portions of the source/drain region 125-3. The placeholder semiconductor layer 115-3 and corresponding buffer semiconductor layer 116-3 are removed using, for example, a selective dry or wet etch process.

Referring to FIGS. 19A-19C, backside source/drain contact 172 is formed in the backside ILD layer 168 in the openings 171 and 171′. Metal layers are deposited in the openings 171 and 171′ to form the backside source/drain contact 172. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering and/or plating, followed by a planarization process such as CMP to remove excess portions of the metal layers from on top of the backside ILD layer 168.

The backside source/drain contact 172 contacts the backside of the source/drain region 125-3. The backside source/drain contact 172 extends through the backside ILD layer 168 to land on and contact the backside of the source/drain region 125-3.

Referring to FIGS. 20A-20C, additional backside ILD material is deposited to form an additional backside ILD layer 168′ on the backside ILD layer 168. A backside power rail 175 (e.g., conductive wires) is formed in portions of the additional backside ILD layer 168′. In forming the backside power rail 175, openings are formed through portions of the additional backside ILD layer 168′. At least one opening exposes a portion the backside source/drain contact 172 on which the backside power rail 175 is formed.

The backside power rail 175 is formed in the additional backside ILD layer 168′ by forming one or more trenches in the additional backside ILD layer 168′ and filling the one or more trenches with conductive material. Trenches may be opened in the additional backside ILD layer 168′ using, for example, lithography followed by RIE. The backside power rail 175 is formed by filling the one or more trenches with conductive material, such as, for example, electrically conductive material including, but not necessarily limited to, tungsten, cobalt, zirconium, tantalum, titanium, aluminum, ruthenium, and/or copper. A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

The backside source/drain contact 172 contacts the source/drain regions 125-3 and the backside power rail 175 is formed on and contacts the backside source/drain contact 172. Backside power delivery network (BSPDN) layers 180 (also referred to herein as backside interconnects) are formed on the backside power rail 175. The BSPDN layers 180 include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETS, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming gate cut portions including an airgap. In the illustrative embodiments, the gate cut portion including the airgap is formed from backside of the semiconductor device and is also disposed between source/drain regions. The presence of the airgap advantageously reduces capacitance between gates of transistors. The airgap is formed after pinch-off of a dielectric liner layer deposited in a conformal deposition process (e.g., ALD or CVD). A cap layer (e.g., frontside cap layer 145) disposed on the gate structures 140 advantageously limits the depth of a backside gate cut so that frontside source/drain contacts in the path of the backside gate cut remain intact.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as +5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a gate cut portion disposed between a first gate region and a second gate region;
wherein the gate cut portion comprises a dielectric liner layer disposed around a vacant area;
wherein the dielectric liner layer encloses the vacant area; and
wherein the gate cut portion isolates the first gate region from the second gate region.

2. The semiconductor device of claim 1, wherein the vacant area comprises air.

3. The semiconductor device of claim 1, wherein the first gate region and the second gate region contact the dielectric liner layer of the gate cut portion.

4. The semiconductor device of claim 1, wherein the gate cut portion is further disposed between a first source/drain region and a second source/drain region.

5. The semiconductor device of claim 4, further comprising a source/drain contact disposed on one of the first source/drain region and the second source/drain region, wherein part of the gate cut portion contacts the source/drain contact.

6. The semiconductor device of claim 5, wherein:
the source/drain contact is disposed on a first side of the one of the first source/drain region and the second source/drain region; and
the semiconductor device further comprises a semiconductor placeholder layer disposed on a second side of the one of the first source/drain region and the second source/drain region opposite the first side.

7. The semiconductor device of claim 4, wherein one of the first source/drain region and the second source/drain region is connected to a backside power delivery network through a backside source/drain contact.

8. The semiconductor device of claim 1, wherein part of the gate cut portion is disposed in an isolation region.

9. The semiconductor device of claim 8, further comprising a spacer layer disposed between the isolation region and the part of the gate cut portion.

10. The semiconductor device of claim 8, wherein the part of the gate cut portion disposed in the isolation region comprises a pinched-off portion of the dielectric liner layer.

11. The semiconductor device of claim 1, further comprising a cap layer disposed on the first gate region, the second gate region and the gate cut portion, wherein the cap layer contacts the gate cut portion.

12. A semiconductor device comprising:
a first nanosheet structure comprising:
a first gate region including a first plurality of gate structures; and
a first plurality of channel layers alternately stacked with the first plurality of gate structures;
a second nanosheet structure comprising:
a second gate region including a second plurality of gate structures; and
a second plurality of channel layers alternately stacked with the second plurality of gate structures; and
a gate cut portion disposed between the first gate region and the second gate region;
wherein the gate cut portion comprises a dielectric liner layer disposed around a vacant area;
wherein the dielectric liner layer encloses the vacant area; and
wherein the gate cut portion isolates the first gate region from the second gate region.

13. The semiconductor device of claim 12, wherein the vacant area comprises air.

14. The semiconductor device of claim 12, wherein the first gate region and the second gate region contact the dielectric liner layer of the gate cut portion.

15. The semiconductor device of claim 12, further comprising:
a first source/drain region disposed on a side of the first nanosheet structure; and
a second source/drain region disposed on a side of the second nanosheet structure;
wherein the gate cut portion is further disposed between the first source/drain region and the second source/drain region.

16. The semiconductor device of claim 15, further comprising a source/drain contact disposed on one of the first source/drain region and the second source/drain region, wherein part of the gate cut portion contacts the source/drain contact.

17. The semiconductor device of claim 12, further comprising a cap layer disposed on the first gate region, the second gate region and the gate cut portion, wherein the cap layer contacts the gate cut portion.

18. A semiconductor device comprising:
a first transistor comprising a first gate region;
a second transistor comprising a second gate region; and
an isolation structure disposed between and contacting the first gate region and the second gate region, wherein the isolation structure comprises a dielectric liner layer disposed around a vacant area, and wherein the dielectric liner layer encloses the vacant area.

19. The semiconductor device of claim 18, wherein the vacant area comprises air.

20. The semiconductor device of claim 18, wherein:
the first transistor further comprises a first source/drain region;
the second transistor further comprises a second source/drain region; and
the isolation structure is further disposed between the first source/drain region and the second source/drain region.
